(19) United States
(12) Patent Application Publication
(10) Pub. No.: US 2006/0267136 A1
(43) Pub. Date: Nov. 30, 2006

(54) INTEGRATED CIRCUIT (IC) WITH ON-CHIP PROGRAMMABLE FUSES

(75) Inventors: Timothy H. Daubenspeck, Colchester, VT (US); Jeffrey P. Gambino, Westford, VT (US); Christopher D. Muzzy, Burlington, VT (US); Wolfgang Sauter, Richmond, VT (US)

Correspondence Address: LAW OFFICE OF CHARLES W. PETERSON, JR. BURLINGTON, 11703 Bowman Green Dr., Suite 100, Reston, VA, 20190, US

(73) Assignee: INTERNATIONAL BUSINESS MACHINES CORPORATION, Armonk, NY (US)

(21) Appl. No.: 10/908,707

(22) Filed: May 24, 2005

(51) Int. Cl. H01L 29/00

(52) U.S. Cl. 257/529

(57) ABSTRACT

An Integrated Circuit (IC) chip with fused circuits and method of making the IC. Fuses in an upper wiring layer are formed using a multi-tone mask to define rounded bottom corners on the fuses, while wiring in the upper wiring layer maintain a rectangular cross-section.

### BACKGROUND OF THE INVENTION

1. Field of the Invention

The present invention is related to Integrated Circuit (IC) chip manufacture and more particularly to forming fuses on IC chips.

2. Background Description

Fuses on Integrated Circuit (IC) chips are well known in the art and are commonly included in IC chips with arrays of identical elements, repetitious identical circuits or even for late (in the manufacturing process) programming, e.g., selectively blowing fuses to set chip select addresses. A Random Access Memory (RAM), for example, includes an array of identical RAM cells. A defect in just one cell could ruin the entire array. So, typically IC chips with such arrays or even numerous identical copies of the same circuit, are designed with extra, identical, replacement copies or spares units, i.e., of array elements or selected chip circuits. When a bad or defective unit is identified, e.g., through chip test, the bad unit may be swapped, electrically, with a good spare copy. Consequently, sparing (swapping a bad unit for an identical on-chip good copy) is well known in the art as a relatively inexpensive repair (e.g., to improve chip manufacturing yield), especially for arrays and repetitive circuits. Typically fuses are included in repetitive circuits and array sections, as well as spare copies. The fuses select/deselect fused units to replace bad sections of a new chip (e.g., at initial chip test) with identical good spare copies.

A RAM array, for example, may be designed with fuse rows and columns and with selectable spare rows and columns. During initial chip test, some chip arrays may have rows and/or columns that test bad. Defective areas may be electrically isolated from the array by blowing the appropriate fuses; normally, changing the fuse from a connection (e.g., between a device an a supply line) to an open circuit. Spares are selected by blowing other fuses to electrically replace the defective rows/columns with spares. Thus, fuses have proven to be important for improving IC chip yield, especially for expensive memory array chips.

Fuses are located, normally, somewhat isolated even from the circuit containing the fuse and at the chip surface with only a thin passivation layer, if any, provided above the fuse. A typical semiconductor chip fuse is a low resistance wire, such as a metal or very low resistance doped semiconductor, e.g., polysilicon. Semiconductor fuses are normally programmed or blown by heating just the fuse until the fuse material reaches a critical temperature, at which point which the fuse opens. For example, fuses may be blown by applying laser energy to the fuse, focusing laser energy just on the fuse to as great an extent possible. Also, fuses may be blown electrically by passing a relatively high current though the fuse for thermal heating. When the fuse blows, fuse material, which is encased in dielectric material, forces itself out of the encasement to open the fused circuit at the blown fuse. So, although the typical upper chip passivation layer is relatively thick, chip designers intentionally thin the upper passivation layer at the fuses, placing an escape “window” above each of the fuses. Ideally, the passivation layer is thin enough in the window to allow the molten fuse material to escape its encasement without damaging circuits, wires and etc., below or in the vicinity of the fuse.

Unfortunately, especially with upper dielectric layers made of softer, mechanically weaker low-k dielectric, all of the programming energy collecting in the fuse does not necessarily escape through the window and, instead, is directed downward and laterally. Since it is difficult to control window thickness, in some instances blowing the fuse fractures the chip dielectric encasing the fuse and cracks adjacent and underlying low-k dielectric layers. At worst, these cracks may radiate through underlying wiring, causing opens and shorts in the chip wiring, i.e., introducing defects or failures into previously good chip areas. These cracks may expose underlying, formerly protected and passivated circuitry to contamination, e.g., moisture. The moisture may reduce chip reliability and, ultimately cause the damaged chip to fail. This may be much harder to diagnose and may not manifest itself until the chip is already in use in the field. Consequently, for these chips the cure may be worse than the defect and blowing fuses to recover failing chips may destroy the chips, turning partially good chips to all bad or suspect, frustrating the purpose of including the fuses in the first place.

Thus, there is a need for fuses for integrated circuits that do not damage the chip when the fuse is blown, especially when the fuses are in low-k dielectric layers.

### SUMMARY OF THE INVENTION

It is a purpose of the invention to improve IC chip yield;

It is another purpose of the invention to eliminate or reduce IC chip damage at programmed fuses;

It is another purpose of the invention to eliminate or reduce IC chip loss at fuse programming;

It is yet another purpose of the invention to damage to circuits adjacent to IC chip fuses caused by programming on the fuses.

The present invention relates to an Integrated Circuit (IC) chip with fused circuits and method of making the IC. Fuses in an upper wiring layer are formed using a multi-tone mask to define rounded bottom corners on the fuses, while wiring in the upper wiring layer maintain a rectangular cross-section.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows the effect on surrounding structures of blowing a prior art fuse;

FIG. 2A shows a cross-sectional example of an Integrated Circuit (IC) chip with preferred embodiment fuse formed according to the present invention;

FIG. 2B shows a cross-section of the preferred embodiment fuse of FIG. 2A through B-B;

FIGS. 3A-C show an example of steps in forming fuses according to a preferred embodiment of present invention.

### DESCRIPTION OF PREFERRED EMBODIMENTS

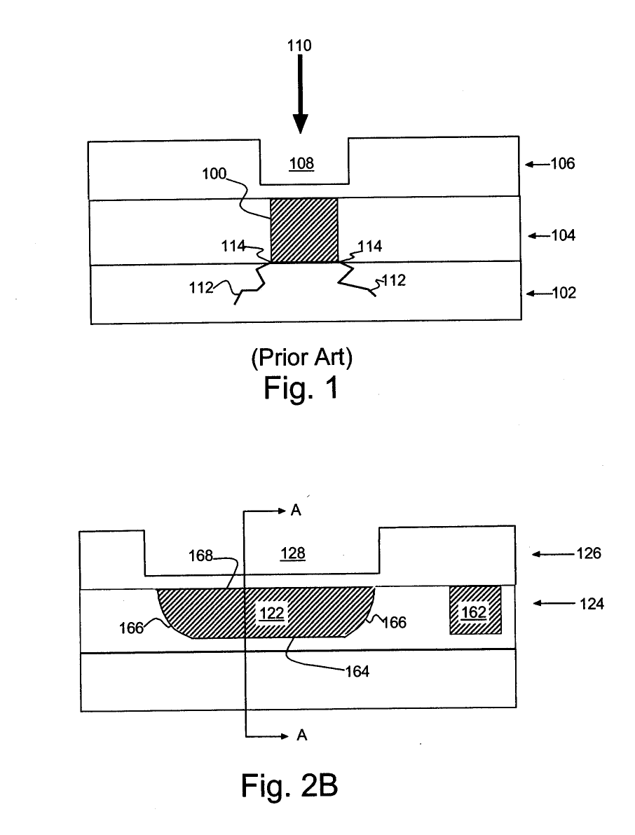

Turning now to the drawings and, more particularly, FIG. 1 shows the effect on surrounding structures of blowing a prior art fuse 100 encased in a dielectric layers 102, 104 and passivation layer 106 (e.g., separating wiring or terminal metallurgy layers) with a thinned dielectric window 108 formed in dielectric layer 106 above the fuse 100. Low-k dielectric materials in the dielectric layers 102, 104 are softer and mechanically weaker than the typical material in the passivation layer 106. So, when energy (e.g., laser energy 110) is applied to the fuse 100, as the fuse material heats and expands some damage 112 is inflicted on the low-k dielectric layers 102, 104 at least until the material fractures the window 108 and escapes through the open window. The severity of the damage varies depending upon any number of factors, e.g., window thickness, fuse thickness and depth, energy source and level and etc. Because etching the passivation layer 106 is imprecise, it is very difficult to control window thickness with any precision. Typically, to avoid over-etching the window 108, the window 108 is left somewhat thicker than might be desired, which can result is damage. This damage can occur during programming because as the fuse is heated, expanding fuse material exerts uniform force on the all sides of the rectangular cross-section of the fuse. If the window is too thick, the force fractures the casing at the lower corners 114 of the softer low-k dielectric layers 102, 104 and radiates from the lower corners 114 until finally the force opens the window 108.

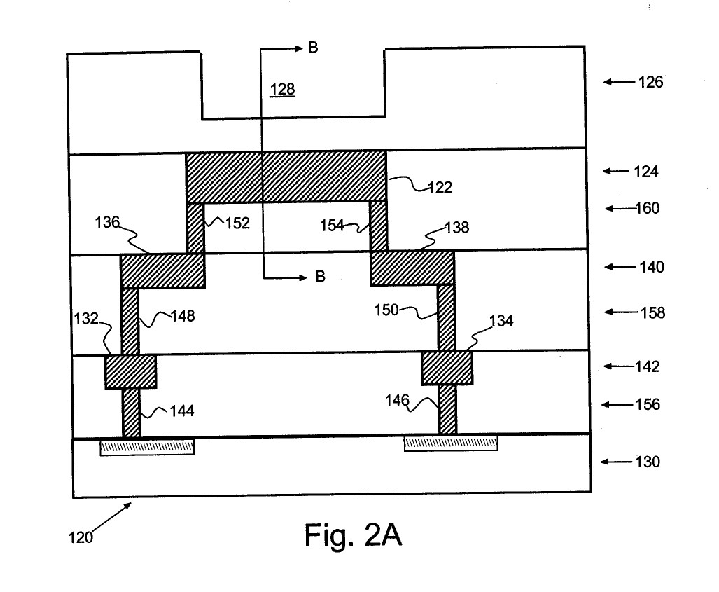

FIG. 2A shows a cross-sectional example of an Integrated Circuit (IC) chip 120 with preferred embodiment fuse 122 formed in a top dielectric layer 124 according to the present invention and covered by a final passivation layer 126. A window 128 in the passivation layer 126 is located above the fuse 122. Fuses 122 may be formed in a top metal layer (e.g., pad metallurgy) or a separate dedicated fuse layer. Typical IC chip elements are formed on one or more circuit layers, e.g., a surface silicon layer 130 of a chip formed in a silicon on insulator (SOI) wafer. The fuse 122 connects to a circuit in the circuit layer 130 or layers, through wires 132, 134, 136, 138 in a number (2 in this example) of intermediate wiring layers 140, 142 and interlevel through vias 144, 146, 148, 150, 152, 154 passing through dielectric layers 156, 158, 160. Existence of the fuse 122 (completing the circuit between interlevel vias 144 and 146) may be treated as a one and removal of the fuse (i.e., blowing the fuse to open the circuit) may be treated as a zero or vice versa. The dielectric layers 130, 156, 158 and 160 may be any suitable dielectric material, preferably, a low-k dielectric. The low-K dielectric may be, for example, SiLK™ dielectric resin from the Dow Chemical Company, any low-K dielectric formed, e.g., by Chemical Vapor Deposition (CVD).

FIG. 2B shows a cross-section of the preferred embodiment fuse 122 of FIG. 2A through B-B and adjacent wiring 162 in the same wiring layer 124 with like elements labeled identically. The bottom surface 164 of fuses 122 formed according to the preferred embodiment of present invention have, preferably, rounded lower corners 166, such that the fuse 122 has other than a rectangular cross-section. Further, rounding may be such that the entire bottom surface 164 is rounded. Preferably, however, the corner arc has an effective radius that is equal to the depth of the fuse 122 and is at least 5% of the depth. The rounded corners 166 of this example distribute the force that the heated fuse material exerts uniformly along the corner arcs rather than at a corner of two orthogonally oriented walls. As a result, instead of applying all of the force in two uniform directions at corners as in the prior art fuse of FIG. 1, the force diffuses at each lower corner 166. Since the upper surface 168 remains unchanged, it applies uniform force to the window 128 and forces cracks (e.g., at the upper corners) to open the window dielectric before any stress even starts to appear on the lower surface 164 or the rounded corners 166. Although shown in this example with rounded corners 166 at the lower surface 164, this is for example only. Instead, the rounded corners 166 may be any shape that replaces the right angle lower corners of the prior art fuse with multiple obtuse angles to disperse the force at the fuse bottom from the expanding fuse material, e.g., each rounded corner may be replaced with an additional side that is inclined between the corner 166 arc endpoints. Wiring 162 sharing the same wiring layer 124 maintains its rectangular shape.

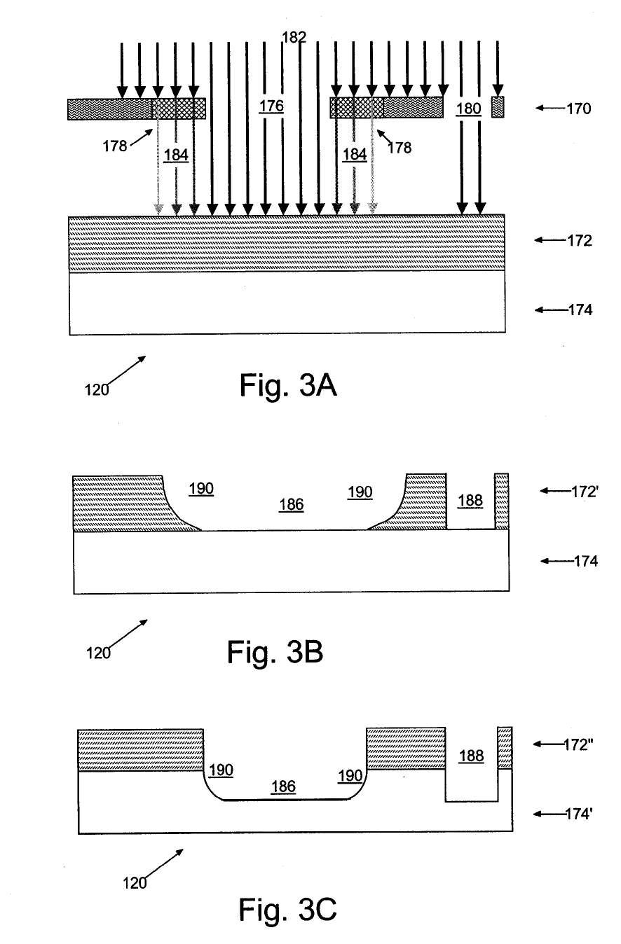

FIGS. 3A-C show an example of steps in forming fuses (e.g., 122 in FIGS. 2A-B) on a semiconductor IC 120 according to a preferred embodiment of present invention. Essentially, in this example, a multi-tone (e.g., dual tone or grey tone) mask 170 defines the fuses in a typical photoresist layer 172 on the top dielectric layer 174 of a typical IC 120. A fuse area defined by the multi tone mask 170 has an open area 176 flanked on each side by partially obstructed areas 178. The partially obstructed areas 178 allow reduced light to penetrate and diffuse through a mask 170. For example, the partially obstructed areas 178 may be a screen-like array or gradient of orifices to allow light to penetrate with decreasing intensity laterally away from the open area 176. By contrast an aperture 180 for a wiring shape (e.g., 162 in FIG. 2B) includes only an open area through the opaque mask without adjacent grey tone areas. So, by exposing the photoresist layer 172 with the mask 170 slightly out of focus, light 182 passes through the open areas 176 and 180 unimpeded and, attenuated light 184 passes through the partially obstructed areas 178. Thus, the exposed photoresist layer 172 defines a fuse mask layer with top dielectric layer 174 fully exposed below the open area 176 and partially exposed with decreasing depth to either side.

Next in FIG. 3B, the exposed photoresist layer is developed and exposed resist is removed to form the fuse and wiring pattern in the fuse mask layer 172′. So, all of the fuse mask layer is removed to the top dielectric layer 174 in fully exposed areas 186, 188 (below the open areas 176, 180) and, removed to either side with decreasing depth, i.e., the undeveloped fuse mask that remains at the sides 190 increases in thickness with distance from the fully exposed areas 186. As a result, while the wiring pattern 188 prints as a rectangular, both sides 190 of the fuse pattern (190, 186, 190) are rounded in developed fuse mask layer 172′ in this example. Alternately, rounding may be less pronounced and each side 190 may be at an incline.

Next, as shown in FIG. 3C, the fuse mask layer is etched to partially remove the mask layer 172″ and print the fuse cross-section into the underlying dielectric layer 174′. Using a typical state of the art wiring layer etchant, the wafer is anisotropically etched until the fuse pattern has been printing into the top dielectric layer 174′. So, for example, a Reactive Ion Etch (RIE) suitable for SiO₂ patterning may be used. Alternately, the fuse pattern may be printed in the top dielectric layer 174′ using an isotropic wet etch (e.g., HF) with high selectivity for the material in the top dielectric 174′ with respect to the fuse mask layer 172″.

However, as the fuse mask layer 172″ is partially removed, the fuse and wiring profiles etch into the underlying top dielectric layer 174′. Once the fuse pattern is printed into top dielectric layer 174′, the fuse mask layer 172″ is completely removed, e.g., using a suitable material for stripping away photoresist. Thus, the fuse and wiring pattern for fuses 122 and wires 162 in FIGS. 2A-B have been printed into the patterned dielectric layer 124. Thereafter, the fuse and wiring pattern is filled with fuse material, e.g., a layer of copper is deposited on the wafer. Excess fuse material is removed, e.g., using chemical-mechanical (chem-mech) polishing to the upper surface of patterned dielectric layer 124, which defines fuses 122 and wires 162. Then, the final passivation layer, e.g., 126 in FIGS. 2A-B, is formed on the chip/wafer surface and windows 128 are formed in the final passivation layer 126 above the fuses 122. Any remaining final chip manufacturing or back end of the line (BEOL) steps follow to complete the IC chip. Fuses 122 may be blown after initial test as described above, to repair chip defects or program ship logic.

Advantageously, however, since the lower corners have been eliminated for preferred embodiment fuses, chip loss at repair or subsequent loss resulting from repair is dramatically reduced over chips designed with prior art fuses.

While the invention has been described in terms of preferred embodiments, those skilled in the art will recognize that the invention can be practiced with modification within the spirit and scope of the appended claims. It is intended that all such variations and modifications fall within the scope of the appended claims. Examples and drawings are, accordingly, to be regarded as illustrative rather than restrictive.

1. An Integrated Circuit (IC) chip comprising:
a plurality of circuits on a circuit layer;
a plurality of wiring layers above said circuit layer and separated by dielectric layers, wires in said wiring layers connecting ones of said plurality of circuits to one another; and
at least one fuse in an upper wiring layer connected to one of said plurality of circuits, wires in said upper wiring layer having a rectangular cross-section and each said at least one fuse having rounded lower corners.

2. An IC chip as in claim 1, wherein said rounded lower corners have an effective radius least 5% of the width of said at least one fuse.

3. An IC chip as in claim 2, wherein said rounded lower corners have an effective radius such that the entire bottom surface of said at least one fuse is rounded.

4. An IC chip as in claim 1, farther comprising;
a passivation layer on said upper wiring layer; and
at least one window in said passivation layer, each said at least one fuse being disposed beneath one said at least one window.

5. An IC chip as in claim 1, wherein said at least one fuse is a copper fuse and said dielectric layers are low-k dielectric layers.

6. An IC chip as in claim 1, wherein said at least one fuse comprises a plurality of fuses, each of said plurality of fuses connected to one of said plurality of circuits.

7. An Integrated Circuit (IC) chip comprising:
a plurality of circuits on a circuit layer;
a plurality of wiring layers above said circuit layer and separated by low-k dielectric layers, wires in said wiring layers connecting ones of said plurality of circuits to one another;
a passivation layer on an upper wiring layer; and
a plurality of copper fuses in said upper wiring layer, each fuse connected to one of said plurality of circuits, wires in said upper wiring layer having a rectangular cross-section and said each fuse having rounded lower corners.

8. An IC chip as in claim 7, wherein said rounded lower corners have an effective radius least 5% of the width of said each fuse.

9. An IC chip as in claim 8, wherein said rounded lower corners have an effective radius such that the entire bottom surface of said each fuse is rounded.

10. An IC chip as in claim 1, further comprising a plurality of windows in said passivation layer, said each fuse being disposed beneath one of said plurality of windows.

11. An IC chip as in claim 10, wherein ones of said plurality of windows being open through said passivation layer, each one of said plurality of fuses disposed beneath an open window being an open circuit.

12-14. (canceled)
